(19) United States
(12) Patent Application Publication
(10) Pub. No.: US 2013/0223082 A1
(43) Pub. Date: Aug. 29, 2013

(54) LED DEVICE FOR THREE-DIMENSIONAL ILLUMINATION

(71) Applicant: Jin Wang, Dongguan (CN)

(72) Inventor: Jin Wang, Dongguan (CN)

(73) Assignee: DONGGUAN LIGHT SOURCE OPTO TECH CO., LTD., TAIPEI (TW)

(21) Appl. No.: 13/699,618

(22) PCT Filed: Sep. 27, 2009
(86) PCT No.: PCT/CN2009/074267

§ 371 Date: Apr. 29, 2013

(51) Int. Cl. H01L 33/48; F21V 3/00; H01L 33/56

(52) U.S. Cl. CPC H01L 33/483; H01L 33/56; F21V 3/00
USPC 362/363; 362/362; 362/368

(57) ABSTRACT

The present invention provides an LED device for three-dimensional illumination, which comprising: a rack 12 and LED chips 2 packaged onto the rack via resin 3; the rack 12 consists of a packaging table 10, and said LED chips 2 are installed on top and all sides of the packaging table 10, such that LED device could emit light on the top and all sides of the packaging table 10. The LED device with wider range of illumination could be widely applied to various lightings.

### BACKGROUND OF INVENTION

1. Field of Invention

The present invention relates generally to an LED technology, and more particularly to an innovative one which enables comprehensive illumination.

2. Description of Related Art

It is well known that, the energy consumption of traditional incandescent lamp is extremely high, and only about 1/10 energy is turned into optical energy, giving rise to huge energy waste. In this reason, new optical sources, such as: energy-saving lamps, are now developed in lieu of the incandescent lamps. Due to lower price and convenience in fabrication, the energy-saving lamps are extensively utilized other than incandescent lamps. Energy-saving lamps are illuminated by the principle of electronic excitation, thus saving more power as compared with incandescent lamps. However, an energy-saving lamp generally contains mercury acting as a medium required for its illumination, leading possibly to mercury pollution during production and after utilization. Besides, energy-saving lamps made of glass are hard to be transported and installed due to the fragility and vulnerability, let alone bigger power consumption and shorter service life.

LED lamps have the following advantages as compared with the aforementioned ones:

1. Energy-saving: the energy consumption of white-light LED lamps accounts for only 1/10 of incandescent lamps and 1/40 of energy-saving lamp.

2. Longer service life: the service life of LED lamps can reach 100,000 h, much longer than incandescent and energy-saving lamps.

3. Available for frequent startup: LED lamps could be started frequently other than traditional energy-saving and incandescent lamps whose filament is easily damaged in the case of frequent turning-on/-off.

4. Solid and enclosed: such types of cold light sources can be easily transported and installed, or placed into any miniature and closed equipments without consideration of vibration or heat dissipation.

5. Environmental-friendly due to absence of harmful substances such as mercury: the components of LED lamps can be easily disassembled and recycled.

Based on above-specified characteristics, LED lamps could replace other lamps gradually. However, LED lamps have specific shortcomings, e.g. limited coverage due to strong directionality, unlike incandescent lamp and energy-saving lamp with radiative sources.

Thus, to overcome the aforementioned problems of the prior art, it would be an advancement if the art to provide an improved structure that can significantly improve the efficacy.

Therefore, the inventor has provided the present invention of practicability after deliberate design and evaluation based on years of experience in the production, development and design of related products.

### SUMMARY OF THE INVENTION

To this end, the following technical scheme is adopted in the present invention:

An LED device for three-dimensional illumination, comprising: a rack and LED chips packaged on the rack via resin; it is characterized by that:

said rack is provided with a packaging table, and LED chips are distributed around and on top of the packaging table.

wherein said rack consists of: a main body and a probe fixed with the main body and insulated to each other; said main body consists of a packaging table and a threaded section, and through-hole is formed within the main body; electrode tips protruding towards the probe are set at top of the packaging table; said probe consists of: a probe body and terminal formed at one end of the probe body; the probe body is inserted from the opening at top of the packaging table, and protruded from the opening of the threaded section; through-holes for penetration by said electrode tips are opened on the terminal.

wherein said packaging table consists of: a flange, and a column located at the center of the flange; the cross section of the column is an equilateral polygon, and an LED chip is distributed at each side of the column.

wherein said probe terminal is located at top of the column, and an insulation pad is set between the terminal and the top of the column; insulant is filled into the through-hole of the main body of the rack into which the probe body is inserted, allowing for insulation of the main body and probe by the insulant and insulation pad.

wherein the flange of said packaging table is of a conical slope; a circular groove is formed on the flange, a transparent cover is embedded into the circular groove, and the resin is poured into the cover.

wherein an electrode lead of LED chip around the column of the packaging table is fixed onto the electrode tip, and the other electrode lead fixed on the terminal of the probe.

wherein said LED rack is gold-plated, and the electrode lead is made of gold wire.

### BRIEF DESCRIPTION OF THE DRAWINGS

FIG. 1: a perspective view of the present invention;

FIG. 2: a principal view of the present invention;

FIG. 3: a sectional view of the present invention;

FIG. 4: a perspective view of the rack of the present invention;

FIG. 5: a top view of the present invention;

FIG. 6: a top view of another preferred embodiment of the present invention.

### DETAILED DESCRIPTION OF THE INVENTION

The present invention will be more readily understood with reference to the accompanying drawings.

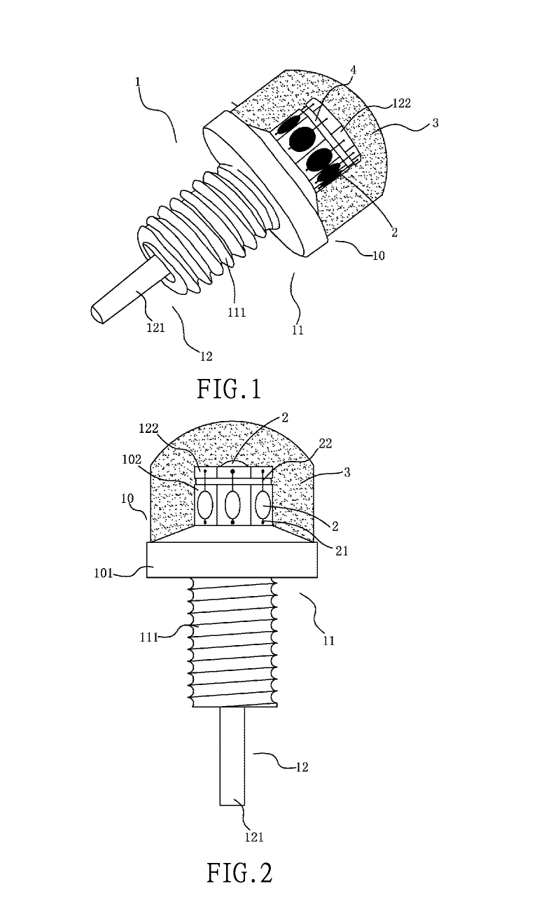

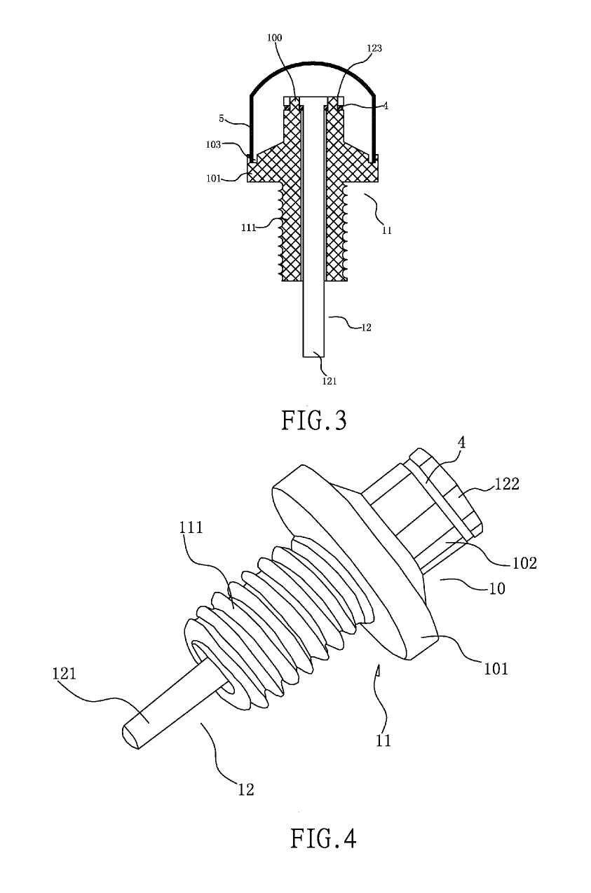

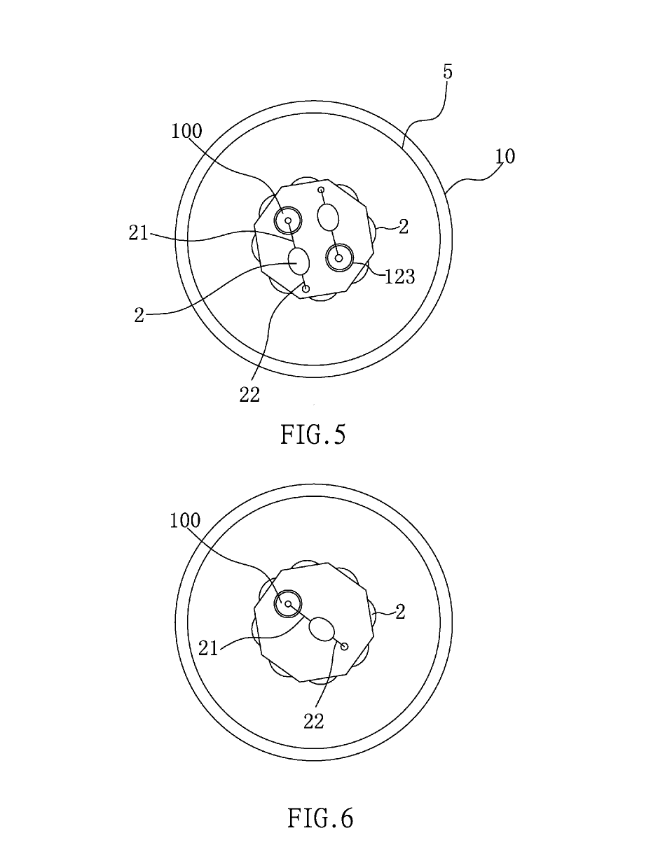

Referring to FIG. 1-5, the preferred embodiment comprises: a rack 1, LED chips 2 and resin 3 for packaging the LED chip 2.

Said rack 1 consists of: a main body 11 and a probe 12 fixed with the main body 11 and insulated to each other. The main body 11 consists of a packaging table 10 and a threaded section 111, and through-hole is formed within the main body 11. Two electrode tips 100 protruding towards the probe 12 are set at top of the packaging table 10 of the main body 11.

Said probe 12 consists of: a probe body 121 and terminal 122 formed at one end of the probe body 121; the probe body 121 is inserted from the opening at top of the packaging table 10, and protruded from the opening of the threaded section 111. Through-holes 123 for penetration by said electrode tip 100 are opened on the terminal 122. That's to say, the electrode tip 100 is protruded from the through-hole 123 and exposed at top surface of the terminal 122. In this preferred embodiment, two electrode tips 100 are set on the packaging table 10.

Said packaging table 10 consists of: a flange 101, and a column 102 located at the center of the flange 101; the cross section of the column 102 is an equilateral polygon, and an LED chip 2 is distributed at each side of the column 102. In this preferred embodiment, the column 102 is of a regular octahedron, i.e., 8 LED is chips 2 are distributed at each side of the column 102, thus realizing 360° illumination.

Alternatively, one or more LED chips 2 are also set on the top surface of the terminal 122 of the probe 12, thus realizing three-dimensional illumination.

The resin 3 is generally made of epoxy resin featuring strong moisture-proofing, insulativity and mechanical strength. So, it has higher refractivity and transmission rate for the light emitted from LED chips 2. A kind of sphere is formed since the resin 3 could cover the entire packaging table 10 and the terminal 122 of the probe 12 on the top surface of the packaging table 10. And the light emitted from LED chips 2 is projected by the resin 3. The flange 101 of the packaging table 10 is of a conical slope that's fit for light reflection; for the purpose of facilitating the packaging of the resin 3, a transparent cover 5 could be installed firstly on the packaging table 10, and resin 3 is poured into the cover 5. For the purpose of facilitating the installation of the cover 5, a circular groove 103 is formed on the flange 101, a transparent cover 5 is embedded into the circular groove 103, and the resin 3 is poured into the cover 5.

In this preferred embodiment, the probe 12 and the main body 11 are insulated to each other: the terminal 122 of the probe 1 is located at top of the column 102, where an insulation pad 4 is set between the terminal 122 and the top of the column 102; and insulant is filled into the through-hole of the main body 11 of the rack 1 into which the probe body 121 is inserted, allowing for insulation of the main body 11 and probe 12 by the insulant and insulation pad 4.

The circuit of the preferred embodiment is installed below: an is electrode lead 21 of LED chip 2 around the column 102 of the packaging table 10 is fixed onto the packaging table 10, and the other electrode lead 22 fixed on the terminal 122 of the probe 12; two LED chips 2 on top of the packaging table 10 are located at top surface of the terminal 122 of the probe 12, of which one electrode lead 21 is fixed on the electrode tip 100 extended from the through-hole 123 on the terminal 122, and the other electrode lead 22 fixed on the terminal 122 of the probe 12.

In this preferred embodiment, the main body 11 in the rack 1 is an electrode of a circuit, and the probe 12 is the other electrode of the circuit; LED chips 2 are connected between the main body 11 and probe 12 to form a loop through the electrode leads 21, 22. The threaded section 111 in the rack 1 allows to install the present invention onto the corresponding interface of the lamp rapidly. The threaded section 111 and the probe body 121 are separately connected with the electrodes in the interface. Given that the terminal 122 and probe body 121 of the probe 12 form a conductor, while the threaded section 111 and the packaging table 10 form a conductor, the LED chips 2 are connected with the power supply for illumination.

Said LED rack is gold-plated for conductor welding.

Referring to FIG. 6, a single electrode tip 100 is provided in the preferred embodiment of the present invention, and also set at different locations for fixation of the LED chips 2.

To sum up, multiple LED chips 2 are packaged on a rack 1 and distributed at 360°, meanwhile LED chips are distributed on the top surface for three-dimensional illumination. Due to the advantages such as compactness, wider range of illumination and convenience of installation, the present invention could be widely applied to various lightings.

1. An LED device for three-dimensional illumination, comprising: a rack (1) and LED chips (2) packaged on the rack (1) via resin (3); it is characterized by that:
said rack (1) is provided with a packaging table (10), and LED chips (2) are distributed around and on top of the packaging table (10).

2. The device defined in claim 1, wherein said rack (1) consists of: a main body (11) and a probe (12) fixed with the main body (11) and insulated to each other; said main body (11) consists of a packaging table (10) and a threaded section (111), and through-hole is formed within the main body (11); electrode tips (100) protruding towards the probe (12) are set at top of the packaging table (10); said probe (12) consists of: a probe body (121) and terminal formed at one end (122) of the probe body (121); the probe body (121) is inserted from the opening at top of the packaging table (10), and protruded from the opening of the threaded section (111); through-holes (123) for penetration by said electrode tips (100) are opened on the terminal.

3. The device defined in claim 2, wherein said packaging table (10) consists of: a flange (101), and a column (102) located at the center of the flange (101); the cross section of the column (102) is an equilateral polygon, and an LED chip (2) is distributed at each side of the column (102).

4. The device defined in claim 3, wherein said probe (12) terminal (122) is located at top of the column (102), and an insulation pad (4) is set between the terminal (122) and the top of the column (102); insulant is filled into the through-hole of the main body (11) of the rack (1) into which the probe body (121) is inserted, allowing for insulation of the main body (11) and probe (12) by the insulant and insulation pad (4).

5. The device defined in claim 3, wherein the flange (101) of said packaging table (10) is of a conical slope; a circular groove (103) is formed on the flange (101), a transparent cover (5) is embedded into the circular groove (103), and the resin (3) is poured into the cover (5).

6. The device defined in claim 4, wherein the flange (101) of said packaging table (10) is of a conical slope; a circular groove (103) is formed on the flange (101), a transparent cover (5) is embedded into the circular groove (103), and the resin (3) is poured into the cover (5).

7. The device defined in claim 5, wherein an electrode lead (21) of LED chip (2) around the column (102) of the packaging table (10) is fixed onto the electrode tip (100), and the other electrode lead (22) fixed on the terminal (122) of the probe (12).

8. The device defined in claim 6, wherein said LED rack (1) is gold-plated, and the electrode lead (21), (22) is made of gold wire.
